(19) United States
(12) Patent Application Publication
(10) Pub. No.: US 2010/0035417 A1
(43) Pub. Date: Feb. 11, 2010

(54) METHOD OF FABRICATING POLYCRYSTALLINE SILICON THIN FILM

(75) Inventor: Pyung-Yong Um, Kyungki-do (KR)

Correspondence Address: THE RAFFERTY PATENT LAW FIRM, 1952 Gallows Road, Suite 200, Vienna, VA, 22182-3823, US

(73) Assignee: EUGENE TECHNOLOGY CO., LTD., Chungcheongnam-do (KR)

(21) Appl. No.: 12/095,729

(22) PCT Filed: Nov. 2, 2006
(86) PCT No.: PCT/KR2006/004531

§ 371 Date: May 30, 2008

(30) Foreign Application Priority Data
Nov. 30, 2005 (KR) 10-2005-0115825

(51) Int. Cl. H01L 21/20

(52) U.S. Cl. 438/482; 438/488; 118/725; 257/E21.09

(57) ABSTRACT

The present invention relates to a method of depositing a polycrystalline silicon thin film within a single chamber through a chemical vapor deposition (CVD) process employing a single wafer technique. Particularly, a fine crystalline structure of the polycrystalline silicon thin film is formed in a columnar shape by using SiH₄ (Silane) as a silicon source gas and maintaining the thin film deposition pressure at a certain level so as to control fine grains to improve uniformity of electrical characteristics, thereby preventing a characteristic degradation of the thin film.

### TECHNICAL FIELD

The present invention relates generally to a method of fabricating a thin film by means of a chemical vapor deposition (CVD) process employing a single wafer technique, and more particularly, to a method of fabricating a thin film in which a fine crystalline structure of a thin film is formed in a columnar shape by using a chemical vapor deposition (CVD) process in which the thin film is formed on a wafer by a chemical reaction within a single chamber using SiH₄ (Silane) as a silicon source gas, and maintaining the thin film deposition pressure at a certain level to control fine grains.

### BACKGROUND ART

In general, the selection of a reactive source gas and equipment and the deposition pressure condition according to its selection is considered to be the most important factor in formation of a polycrystalline silicon thin film.

Conventionally, a furnace method is employed to fabricate the polycrystalline silicon thin film. However, in case of fabricating the film having a thin silicon crystalline structure with a thickness of less than 400 Å it is nearly impossible to form a thin film having a polycrystalline structure. Therefore, in order to solve the above problem, the conventional furnace method features that the crystallization of an amorphous thin film is applied to a semiconductor device. In this case, as shown in FIG. 1, there occurs shortcomings in that crystalline uniformity of a polycrystalline silicon thin film formed is very poor, so that if the thin film is used as a floating gate electrode of a semiconductor flash memory, etc., VT uniformity of a semiconductor device is greatly degraded in terms of crystalline uniformity, durability and reliability by the threshold voltage shift, etc., of the device due to the over-erase phenomenon of the device, thereby deteriorating the characteristics of the device.

More specifically, first, an amorphous silicon thin film which does not a crystalline structure is grown using SiH₄ gas or Si₂H₆ gas at a given process temperature, i.e., at 650 C or less, and then the grown thin film is crystallized by a subsequent thermal process (for example, at 650° C. to 900° C.). As a result, as shown in FIG. 1, it can be seen that a planar crystalline structure of the thin film has been photographed by a transmission electron microscope (TEM).

In the case where a gate electrode of a semiconductor device such as a flash memory is formed using such processes, since the size of crystallized grains of the thin film is very irregular, grains having a size of several tens of Å to several hundreds of are formed. Thus, if a transistor is formed using the thin film, the electron transfer rate in the transistor varies. That is, one to two grain boundaries are formed at a region where a grain is very large whereas a number of grain boundaries are formed at a region where a grain is very small so that a tunnel oxide is formed in an oxide valley shape at a lower portion of a region where adjacent grains meet. At this time, a larger oxide valley is formed at a lower portion of a grain boundary between larger grains, and hence a larger amount of phosphorus is concentrated at the lower portion of the grain boundary upon the subsequent phosphorus poly-process to thereby reduce the local barrier height (LBH), so that the larger oxide valley becomes an over-erase point or an electron trap formation site caused by phosphorus upon the driving of a device, thereby significantly deteriorating a reliability of the device. As a result, after a transistor is formed with the transfer of electrons, there is a great difference in the driving capability of several transistors contained in one chip of the device when driving the device, thereby causing the device characteristics to be greatly degraded.

### DISCLOSURE OF INVENTION

### Technical Problem

Accordingly, the present invention has been made to solve the above problems occurring in the prior art, and it is an object of the present invention to provide a method of fabricating a polycrystalline silicon thin film, in which its fine crystalline structure is formed in a columnar shape using a chemical vapor deposition (CVD) process.

### Technical Solution

The above object is accomplished by a method and apparatus for fabricating a polycrystalline silicon thin film, in which a fine crystalline structure of a thin film is formed in a columnar shape by using a chemical vapor deposition (CVD) process in which the thin film is formed on a wafer by a chemical reaction within a single chamber using SiH₄ (Silane) as a reactive source gas, and maintaining the thin film deposition pressure at a certain level to form the crystalline structure through the control of fine grains.

### Advantageous Effects

According to the present invention, a polycrystalline silicon thin film having a columnar-shaped fine crystalline structure is formed by using the chemical vapor deposition (CVD) process within a single wafer-type chamber using SiH₄ (Silane) as a silicon source gas, and the process temperature and pressure is maintained at a certain level to control fine grains to thereby form a columnar-shaped polycrystalline silicon thin film and a uniform grain. Therefore, in case where the thin film is used as a floating gate electrode of a semiconductor flash memory, etc., uniform-shaped grains are formed, an oxide valley of a portion abutting against a tunnel oxide is also formed uniformly at a lower portion of a grain boundary region between a grain and an adjacent grain, i.e., a region where adjacent grains meet, thereby securing durability and reliability of semiconductor device. In addition, in case where the characteristics of the polycrystalline silicon thin film are used in DRAM, SRAM, and LOGIC devices, an excellent device characteristic can be secured, thereby increasing a yield and improving the device characteristics upon the fabrication of the semiconductor device employing the polycrystalline silicon thin film.

### BRIEF DESCRIPTION OF THE DRAWINGS

FIG. 1 is a conceptual view illustrating a polycrystalline silicon thin film having grains whose crystalline uniformity is very poor in case of employing a conventional process;

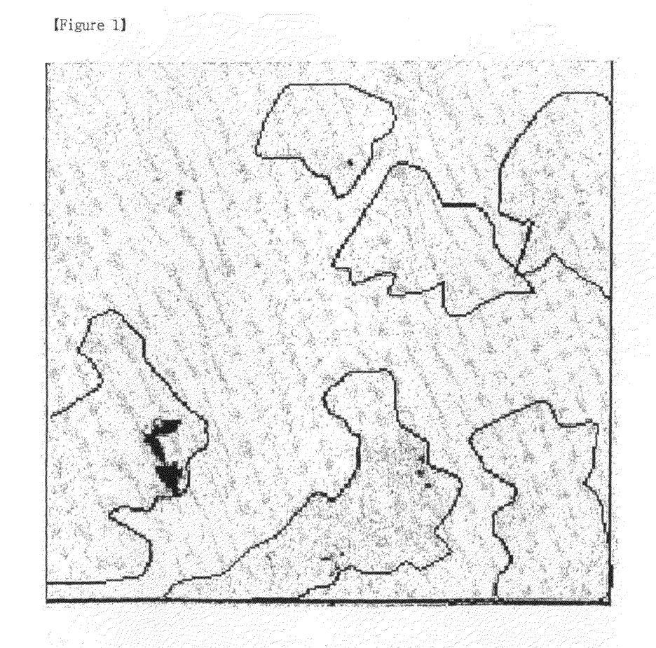

FIG. 2 is a conceptual view illustrating the structure of a single chamber according to the present invention;

FIG. 3 is a graph illustrating the relationship between pressure/temperature and refractive index in the crystalline structure of the thin film formed according to the present invention;

FIGS. 4 and 5 are conceptual views illustrating the crystalline structure of a polycrystalline silicon thin film formed in a columnar shape according to one embodiment of the present invention; and

FIGS. 6 and 7 are conceptual views illustrating the crystalline structure of a polycrystalline silicon thin film formed in a columnar shape according to another embodiment of the present invention.

### MODE FOR THE INVENTION

Hereinafter, the present invention will be described in detail with reference to the accompanying drawings.

The present invention is directed to a method of fabricating a polycrystalline silicon thin film having a fine crystalline structure formed in a columnar shape in a semiconductor device using the CVD process within a single chamber.

In general, the chemical vapor deposition (CVD) refers to a process in which a source gas is supplied to induce a chemical reaction with a substrate to thereby form a thin film on a semiconductor substrate.

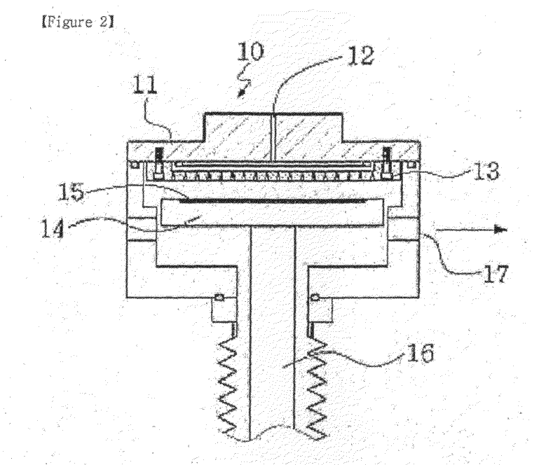

The CVD process performed within the single chamber will be described hereinafter with reference to FIG. 2.

Referring to FIG. 2, first, a single chamber 11 is formed at an upper portion thereof with a gas-introducing portion 12 for introducing a source gas into the chamber therethrough. The source gas introduced through the gas-introducing portion 12 is injected into the chamber 11 through a shower head 13.

Also, the wafer 15 on which the thin film is to be deposited is placed on the heater 14. At this time, the heater 14 is supported by a heater support 16. The deposition process is performed by such a thin film fabricating apparatus to form a thin film deposited wafer, which is in turn discharged to the outside through a vacuum port 17 formed at a side wall of the chamber 11.

The SiH₄ gas is introduced onto the wafer substrate in the chamber 11 by the chemical vapor deposition (CVD) process employing such a single wafer technique so that the reaction gas decomposed by thermal decomposition flows over the surface of a silicon substrate disposed on the heater to thereby deposit a thin film on the wafer substrate.

At this time, the temperature and pressure condition required for the deposition is an important one among technical factors constituting the present invention.

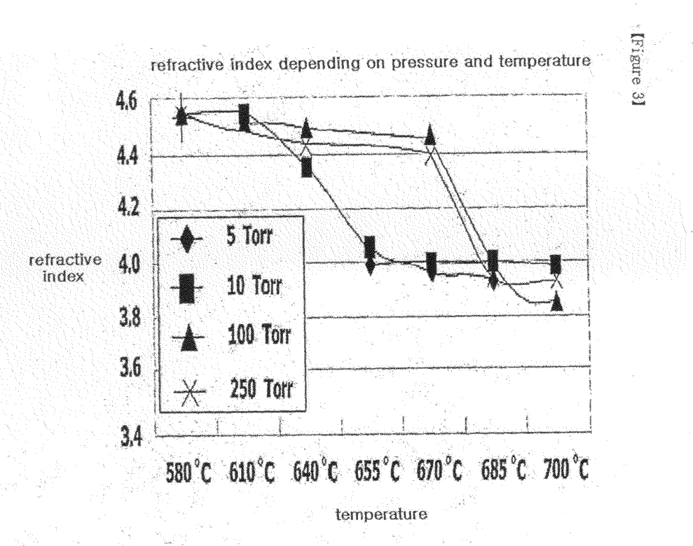

FIG. 3 is a graph illustrating the relationship between pressure/temperature and refractive index in the crystalline structure of a silicon thin film formed according to the process of the present invention.

As shown in FIG. 3, the abscissa denotes the temperature set in the thin film fabricating process, and the ordinate denotes the refractive index (R.I) allowing for recognition of the crystalline properties of the thin film deposited on the wafer.

As the refractive index approaches 4.5, the silicon thin film is grown into an amorphous state whereas as it approaches 4.0, the silicon thin film is formed into a crystalline material of a polycrystalline state.

In the meantime, the crystalline material refers to s solid having three-dimensional periodicity in atomic arrangement. A solid no having this three-dimensional periodicity is called a non-crystalline material (i.e., amorphous material). A semiconductor using such an amorphous state may include an amorphous silicon. Since this amorphous semiconductor can be deposited on a large-sized substrate at a low temperature, it is used in a thin film transistor.

As shown in FIG. 3, in the crystalline structure of a silicon thin film, there occurs a variation in refractive index measured depending on pressure at a process temperature ranging from 640 C to 685 C. As an example, it can be seen from the graph that in case where the source gas is introduced uniformly during the deposition process, when the process temperature is 650 C and the process pressure is less than 10 Torr, the measured refractive index value is close to 4.0 so that a columnar-shaped polycrystalline silicon thin film is formed. On the other hand, when the process pressure during the deposition process is more than 100 Torr, the measured refractive index value is close to 4.5 so that an amorphous silicon thin film is formed. As the same example, it can be seen from the graph that in case where the source gas is introduced uniformly during deposition process, although the process pressure is less than a given pressure at a temperature of more than 685 C, the amorphous silicon thin film is not formed any more. That is, it can be understood from the graph that the polycrystalline silicon thin film can be formed at a temperature of 685 C and a pressure of less than 10 Torr as well as the refractive index measured under a process condition where the process pressure is more than 100 Torr is close to 4.0.

In the meantime, a surface roughness is used as a coefficient for evaluating the performance of the deposited thin film. In the present invention, the Atomic Force Microscopy (AFM) is used and the Root Mean Square (RMS) is used as the calculation method. As a result, the surface roughness most preferably is 2.

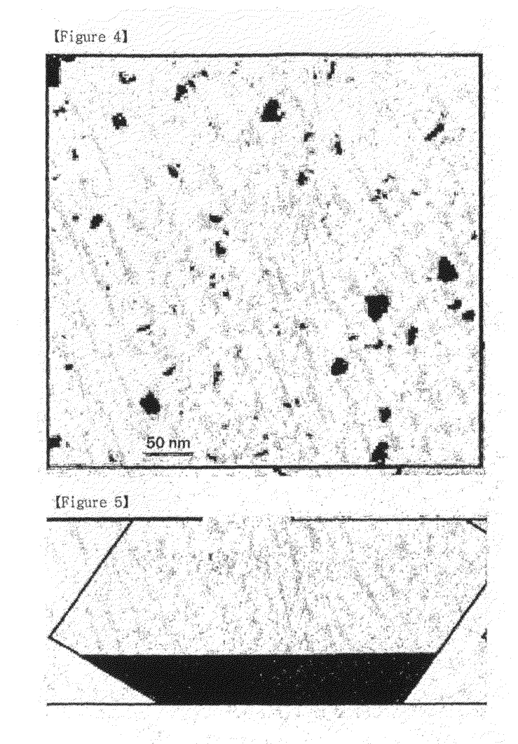

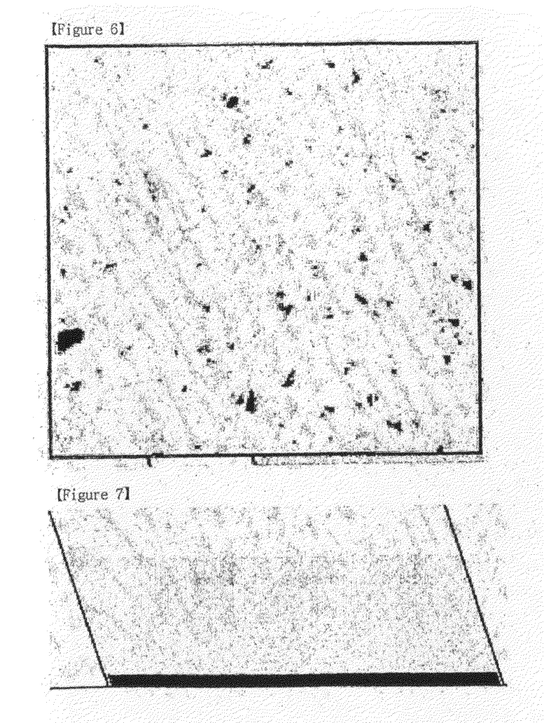

FIGS. 4 and 5 illustrate the crystalline structure of a columnar-shaped polycrystalline silicon thin film deposited at a temperature of 685 C and a pressure of 10 Torr according to one embodiment of the present invention, and FIGS. 6 and 7 illustrate the crystalline structure of a columnar-shaped polycrystalline silicon thin film formed at a temperature of 730° C. and a pressure of 10 Torr according to another embodiment of the present invention.

As described above, SiH₄ (Silane) is used as a source gas proposed in the present invention without departing from the spirit of the present invention, but Si₂H₆ gas is used as another source gas. Accordingly, another embodiment of the present invention features that a columnar-shaped grain structure is formed at a constant temperature and a constant pressure, and a crystalline structure in which an equiaxed-shaped grain structure and an amorphous silicon thin film are mixed within the spirit of the present invention, or an amorphous silicon thin film is formed.

Further, SiH₄ (Silane) is used as a source gas proposed in the present invention without departing from the spirit of the present invention, but Si₂H₆ gas is used as another source gas. Accordingly, another embodiment of the present invention features that when a columnar-shaped grain structure is formed at a constant temperature and a constant pressure, H₂ as an impurity gas is injected into the chamber to control the process pressure to be uniform such that a crystalline structure in which an equiaxed-shaped grain structure and an amorphous silicon thin film are mixed within the spirit of the present invention, or an amorphous silicon thin film.

### INDUSTRIAL APPLICABILITY

Therefore, according to the present invention, a polycrystalline silicon thin film having a columnar-shaped fine crystalline structure is formed by using the chemical vapor deposition (CVD) process within a single wafer-type chamber using SiH₄ (Silane) as a silicon source gas, and the process temperature and pressure is maintained at a certain level to control fine grains to thereby form a columnar-shaped polycrystalline silicon thin film and a uniform grain. Therefore, in case where the thin film is used as a floating gate electrode of a semiconductor flash memory, etc., uniform-shaped grains are formed, an oxide valley of a portion abutting against a tunnel oxide is also formed uniformly at a lower portion of a grain boundary region between a grain and an adjacent grain, i.e., a region where adjacent grains meet, thereby securing durability and reliability of semiconductor device. In addition, in case where the characteristics of the polycrystalline silicon thin film are used in DRAM, SRAM, and LOGIC devices, an excellent device characteristic can be secured, thereby increasing a yield and improving the device characteristics upon the fabrication of the semi-conductor device employing the polycrystalline silicon thin film.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A method of fabricating a polycrystalline silicon thin film by means of a chemical vapor deposition (CVD) process employing a single wafer technique, wherein during the CVD process, SiH₄ (Silane) gas is used as a silicon source gas and a process temperature is set to be within a range between 640° C. and 770° C.

2. The method as defined in claim 1, wherein a surface roughness according to the thin film fabricating method is 2.

3. The method as defined in claim 1, wherein the process temperature is set to be within a range between 640 C and 680 C and a process pressure is set to be less than 10 Torr so that the crystalline structure of the thin film has a columnar shape.

4. The method as defined in claim 1, wherein the process temperature is set to be within a range between 640 C and 680 C and a process pressure is set to be within a range between 10 Torr and 50 Torr so as to form a crystalline and amorphous silicon thin film.

5. The method as defined in claim 1, wherein the process temperature is set to be within a range between 640° C. and 680° C. and a process pressure is set to be more than 50 Torr so as to form an amorphous silicon thin film.

6. A method of fabricating a polycrystalline silicon thin film by means of a chemical vapor deposition (CVD) process employing a single wafer technique, wherein during the CVD process, Si₂H₆ gas is used as a silicon source gas and a process temperature is set to be within a range between 640° C. and 780° C.

7. The method as defined in claim 6, wherein a process pressure during the fabrication of the thin film is set to be within a range between 10 Torr and 50 Torr.

8. A method of fabricating a polycrystalline silicon thin film by means of a chemical vapor deposition (CVD) process employing a single wafer technique, wherein during the CVD process, SiH₄ (Silane) gas or Si₂H₆ gas is used as a silicon source gas, H₂ as an impurity gas is injected into the chamber concurrently, at which time, a process pressure is set to be within a range between 1 Torr and 50 Torr.

9. The method as defined in claim 1, wherein the flow rate of SiH₄ (Silane) gas as the silicon source gas is set to be within a range between 1 SCCM and 300 SCCM.

10. An apparatus for fabricating a polycrystalline silicon thin film using a chemical vapor deposition (CVD) process of the method according to claim 1, comprising:
a reaction chamber 11 having a gas-introducing portion 12 formed at an upper portion thereof for introducing a source gas into a reaction chamber therethrough, and a vacuum port 17 formed at a side wall thereof for discharging the source gas therethrough after the deposition of the thin film;
a shower head 13 for injecting the source gas introduced through the gas-introducing portion 12 into the chamber;
a heater 14 for placing a wafer for deposition thereon;
and
a heater support 16 for supporting the heater.
